(19) United States
(12) Patent Application Publication
(10) Pub. No.: US 2005/0214692 A1
(43) Pub. Date: Sep. 29, 2005

(54) Method for producing microhole structures

(76) Inventors: Andreas Gombert, Freiburg (DE); Volkmar Boerner, Freiburg (DE); Josef Robert, Oelde (DE); Ilka Gehrke, Oberhausen (DE); Benedikt Blasi, Freiburg (DE); Michael Niggemann, Freiburg (DE); Christian Schlemmer, Freiburg (DE)

Correspondence Address: BARNES & THORNBURG, P.O. BOX 2786, CHICAGO, IL, 60690-2786, US

(21) Appl. No.: 10/512,601

(22) PCT Filed: Apr. 25, 2003
(86) PCT No.: PCT/EP03/04321

§ 371 Date: May 31, 2005

(30) Foreign Application Priority Data
Apr. 26, 2002 (DE) 102 19 584.6

(51) Int. Cl. G03F 7/00

(52) U.S. Cl. 430/322

(57) ABSTRACT

The invention relates to a novel method for producing microhole structures. According to said method, the material used to produce said microhole structures is applied to a substrate surface provided with a relief structure, by means of an angular coating process. In order to achieve the desired pattern of holes, the relief structure has a continuous network of first surface elements and second surface elements located thereinbetween, the local surface normal vectors of the first surface elements forming a small angle with the unit vector, and the local surface normal vectors of the second surface elements forming a small angle with the direction vector of the coating.

The invention relates to a method for manufacturing microhole structures.

Microhole structures for the fine filtration for example of fluids and for the filtering of radiation or for the shielding of radiation have been known for a long time. Here, it is usually the case of regular hole structures with webs between the holes, which are connected in a large-surfaced manner. For the filtering of radiation or shielding of radiation, the webs are mostly metallic and have a high conductivity. Metallic and non-metallic materials are suitable for fine filtration. Since microhole structures with very thin webs when unsupported have a stability which is too low for the filtration, these are supported by a second grid which is considerably larger with respect to the dimensions of the hole and web. For filtering the radiation, the hole structures may be located on a substrate which is optically transparent in the wavelength region which is of interest with regard to the filtering. The holes of these microhole structures may be almost round or may also be elongate in one direction. Typical dimensions of the holes lie in the region of 0.1 μm to 100 μm. In particular, the manufacture of microhole structures with typical hole dimensions in at least one direction of 0.1 μm to 100 μm has been very expensive up to now since very expensive structuring methods such as the LIGA method or photolithography and interference lithography have been needed to be used for this, in combination with etching or lift-off techniques.

Hole structures with minimal hole dimensions of >approx. 1 μm may be formed in the laboratory lithographically by way of contact exposure. With this, firstly a mask is created by way of electron-beam writing. This, for duplication, is pressed against a substrate coated with a photoresist, e.g. a thin film onto glass or silicon. During the exposure procedure only the regions of the photoresist which are not covered by the mask are irradiated with UV-radiation. In the exposed regions the photoresist has a significantly different solubility rate in the subsequent development process in comparison to the unexposed regions. With positive resists, the exposed regions dissolve quicker, with negative resists the unexposed ones. Due to this, after developing, a surface relief arises, which given a suitable selection of the exposure and developing parameters, masks the very thin film at the location of the webs and leaves them free at the location of the holes. The film may subsequently be etched in a wet-chemical manner or by way of ion-etching, and the photoresist may be removed.

Another technology is the lift-off method. With this, firstly the substrate is coated with photoresist and this is structurised. Subsequently the substrate including the photoresist structure is provided with the thin film by way of a vacuum method such as vapour deposition or sputtering. By way of dissolving the photoresist structure, the film is lifted away at these locations. The mask for etched structures and for structures according to the lift-off method, given an otherwise equal processing, need to be complementary.

Photolithography in combination with electroshaping is also counted as belonging to the known structuring methods, which is particularly applied to thick layers which are to be structured. This method is also indicated as a low-cost LIGA method.

The contact exposure method has the disadvantage that it may not be used industrially for hole dimensions <1 μm, since the reject rate would become too high due to the unavoidable variation of the distance between the mask and the substrate.

The exposure of the photoresist may also be effected with projection exposure methods. With this, the mask is typically projected onto the photoresist layer, reduced in size in a ratio of 5:1. The whole substrate is exposed in a step-and-repeat process by way of repeated exposure of the same pattern on the mask. The projection exposure has the advantage that with this method one may also industrially manufacture structures <1 μm in the photoresist layer. However, a projection exposure machine with exposure wavelengths in the low UV region are required. Such projection exposure machines have high investment costs. Furthermore for the projection exposure, on account of the low depth of field of the imaging, one further requires extremely plane substrates which as a rule may only be obtained by way of expensive surface treatment processes such a lapping and polishing. This means that the costs for the substrate to be applied increase.

Interference lithography is particularly suitable for the formation of periodic structures (grid structures) which has already been suggested for the manufacture of microhole structures. With this technique, the photoresist with the interference pattern is exposed to at least two or more coherent wave fields which superimpose. The period A of the grid, given a symmetrical incidence of the two waves, is given by the following relation:
Λ=λ₀/2sinθᵢ
with λ₀ equal to the wavelength of the coherent wave fields and θᵢ equal to the angle which the propagation directions of the incident waves encloses with the normal to the exposed surface.

With this, line grids are produced on exposure. The manufacture of crossed grids and hexagonal grids by way of two subsequent exposures with the intermediate rotation of the substrate by 90° and 60° respectively is also known. After developing the photoresist, either free-standing photoresist columns, or a continuous surface relief arises.

The coating of linear surface relief grids under oblique incidence is known for manufacture of polarisers for the near infra-red. Due to the casting of the shadow, only one flank of the line grid is coated. For this, one mostly uses vapour deposition methods. It is however also possible to apply specially optimised sputter techniques. In the case of the polariser, with oblique coatings with a metal, one may then speak of self-adjusted metallic strip conductors. A transfer of this technology to the manufacture of microhole structures is however not obvious since the oblique coating of crossed grids or hexagonal grids would lead to great demands with regard to adjustment (trimming). The propagation direction of the coating cluster varies over the surface of the substrate. The casting of the shadow in a first approximation may be observed as the casting of a shadow of a point light source. Since however the distance between the source and the substrate in a vacuum apparatus may not be selected infinitely large, a local change of the propagation direction may not be avoided. Thus only surface reliefs which, as in the case of a line grid, are tolerant with respect to a change of the propagation direction of the coating cluster, are suitable as self-adjusting masks for oblique coating.

It is the object of the present invention to specify a method for manufacture of microhole structures which is inexpensive and permits minimal hole dimensions of up to 0.1 μm.

According to the invention, this object is achieved by a method with the features of claim 1. Advantageous further embodiments of the method according to the invention are to be deduced from the dependent claims.

By way of the formation of a substrate with a relief structure on a surface and an oblique coating of the relief structure with the material of the microhole structure, the substrate itself is used as a mask so that inasmuch as this is concerned, one requires no adjustment (trimming) (“self-adjustment”), and the inaccuracies which this entails are avoided. By way of this it is rendered possible to obtain hole dimensions of down to 0.1 μm in an industrial manner.

For achieving the desired formation as a microhole structure, it is necessary for the relief structure to have a continuous network of first surface regions whose local surface normal vectors enclose a small angle with the unit vector of the surface, and of second surface regions between the first surface regions, whose local surface normal vectors enclose a small angle with the direction vector of the coating.

A particular economical efficiency of the method results if the relief structure of the substrate is formed by replication, of an original structure. At the same time, the original structure is preferably formed by a photolithographic method, in particular by way of interference lithography, and an embossing punch of this is manufactured by way of galvanic deformation. By way of a subsequent process such as embossing or casting, the relief structure may be copied onto a multitude of substrates. Preferred materials into which the relief may be replicated are plastics, sol-gel layers and glass.

The invention is hereinafter described by way of the embodiment examples represented in the Figures. There are shown in:

FIG. 1 the formation of a relief structure with truncated cone shaped projections on a substrate surface,

FIG. 2 the acting manner of the oblique coating with the relief structure according to FIG. 1,

FIG. 3 the acting manner of the oblique coating with a relief structure with truncated cone shaped recesses,

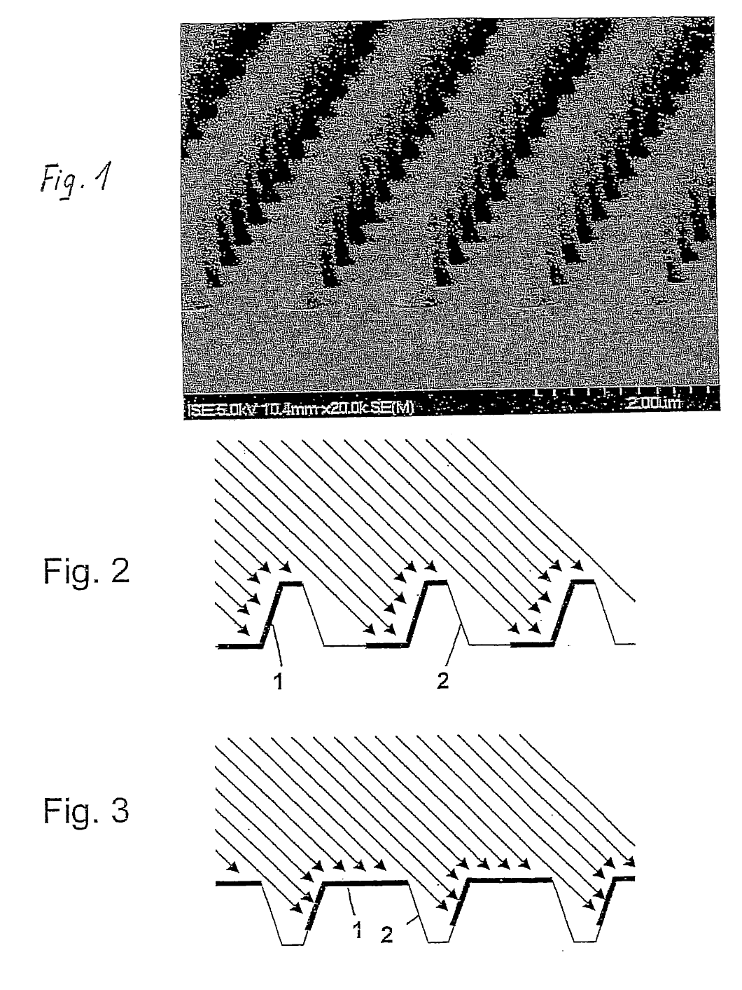

FIG. 4 a metallic microhole structure for filtering infrared radiation, and

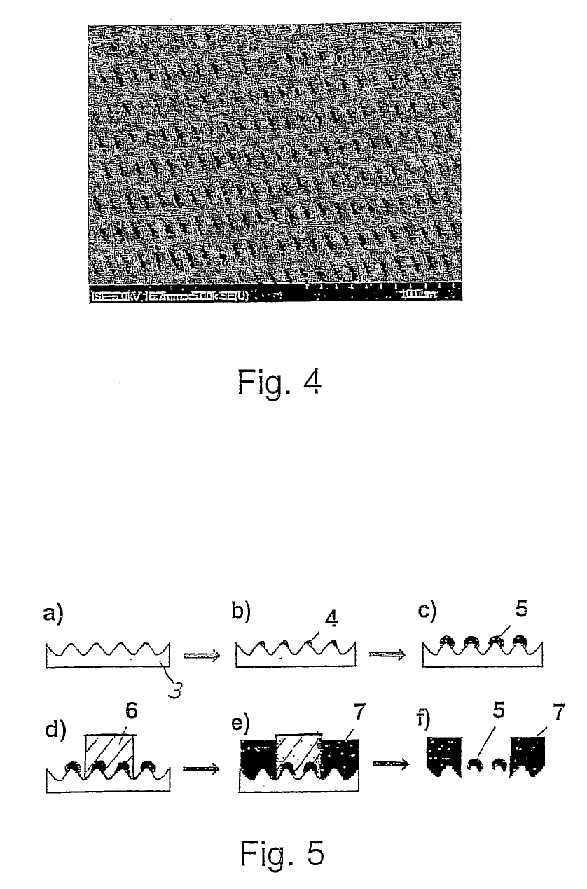

FIG. 5 the course of the process with the manufacture of a microhole structure for the fine filtration of fluids.

The oblique coating has a preferred direction of coating. This, in the case of known oblique coating of linear structures, is selected perpendicular to the direction of the translation invariancy. For the oblique coating for the production of hole structures there is the new requirement that the casting of the shadow of the raised region of the surface structure does not lead to an interruption of the web structure surrounding the hole. This may be ensured by various embodiments of the surface relief:
A) an arrangement of parallelepiped, cylinder-shaped and truncated cone shaped as well as similar projections on a plane or approximately plane surface. With this arrangement the structure heights and the direction of incidence of the coating material need to be matched to one another in a very accurate manner, i.e. this arrangement is sensitive to adjustment. Changes in the coating direction lead very quickly to a change in the hole shape.

FIG. 1 shows a perspective representation of such an arrangement with which the projections are truncated cone shaped. FIG. 2 represents the oblique coating of this arrangement, from which the coated regions 1 and the non-coated regions 2 lying in the shadow of the projections may be seen.
B) The negative of the surface relief from A): recesses in a plane or approximately plane surface. This arrangement is considerably more advantageous than arrangement A). However, regions of the wall of the recess are also coated. This relief structure may be obtained by way of replication of an original structure in the design of the arrangement A). FIG. 3 schematically shows the oblique coating of the arrangement B).
C) A continuous surface relief which, observed in one direction (x-direction), is modulated alternately to a greater and then to a lesser extent and in the direction perpendicular to this (y-direction) comprises webs at shorter distances. With the oblique coating in the x-direction, the weakly modulated regions are fully coated. The webs in the y-direction on account of the casting of the shadow produce the hole structures with the oblique coating. The more elongate the hole structures, the less sensitive is the structure with respect to adjustment (trimming) errors with the oblique coating.

FIG. 4 in a plan view shows a metallic microhole structure for filtering infrared radiation, which has been obtained by way of oblique coating of such a relief structure.

For the three mentioned designs A), B) and C) of the surface relief, the two following conditions are valid, with the assumption that these extend in a x-y plane.
Condition 1: The structure must have a continuous network of surface regions, whose local surface normal vectors n enclose a small angle with the unit vector z perpendicular to the x-y plane: n≈z (coated regions).
Condition 2: The structure between the network from condition 1 must have as large as possible surface regions whose local surface normal vectors n enclose a small angle with the direction vector of the coating b: n≈b (non-coated or shading regions).

Elongate structures are particularly favourable since with these there result particularly large surface regions which fulfil condition 2. Furthermore blazed structures are particularly favourable since with their steep flank n and b they enclose a particularly small angle if the steep flank is distant to the coating source.

The surface reliefs A) to C) may be manufactured in a particularly efficient manner by way of interference lithography. The relief A) may be manufactured using a positive photoresist. By way of a simple recopying by way of galvanic or other replication processes, a more favourable structure B) arises. A similar structure to B) such as e.g. in a hexagonal arrangement may also be manufactured by way of interference lithography with three or more incident waves. Elongate holes according to the structure type C) may be very easily manufactured by way of double exposures with the intermediate rotation of the sample holder about 1°-85°. With a rotational angle of 1°, the elongation is very large; with a rotational angle of 85° the elongation is very low.

In the following, the manufacture of microhole structures obtained by oblique exposure, for different application purposes are described.

1. The Manufacture of Filters for Infrared Radiation.

A suitable surface relief is replicated in polyethylene (PE) or polytetrafluorethylene (PTFE) which are transparent to infrared radiation and is obliquely coated with a metal of a high conductivity, e.g. gold. The filter is capable of functioning after the oblique coating. The wavelength of the peak transmission is determined by the hole dimensions and the refractive index of the hole, the polarisation dependency on the hole shape. A filter obtained in this manner is shown in FIG. 4 in which the obliquely coated surface relief is imaged such that only the metal grid is to be seen. After the oblique coating, an infrared-transparent protective coating is applied. By way of this, the wavelength of the peak transmission changes.

2. Microhole Structures for the Fine Filtration of Fluids

With the manufacture of microhole structures for the fine filtration of fluids, one needs to take several provisions for mechanically reinforcing the obliquely coated screen structure. This is effected by way of galvanic reinforcement of the microscreen and by way of depositing a support grid. The support grid may either be generated directly on the microscreen or separately from this and then deposited onto the microscreen. In the first case the structurisation of the support grid may be realised in a particularly economical manner by way of printing processes. It may be necessary to also galvanically manufacture the support grid. In this case the negative structure of the support grid is printed. In FIG. 5 an exemplary process course with two galvanic steps is shown.

In this, a) shows the substrate 3 provided with the surface structure; b) represents this after the oblique coating with a metal 4; and c) represents the arrangement after the galvanic reinforcement of the coating material with nickel 5. In d) the arrangement with the negative structure 6 of the support grid consisting of organic material is shown and e) shows the arrangement after a further galvanic treatment with nickel, with which the support grid 7 has been formed. In f) the finished screen is shown, with which the organic components, specifically the substrate 3 and the negative structure 7 have been removed.

It is alternatively possible to print on the support grid itself.

3. The Manufacture of Microhole Structures for Shielding Electromagnetic Radiation.

Microhole structures for shielding undesired electromagnetic radiation are often required on glass surfaces, e.g. cover glasses of plasma displays. The essential function of the microhole structure is to achieve a very good direct-current conductivity with a good visual transmission. The additional task which is accomplished by this embodiment example is the transfer of a microhole structure onto the glass plate. This is achieved by two variants. In the first variant the glass plate is functionalised on the surface such that the metallic microhole structure sticks better to the glass surface than on the obliquely-coated substrate serving as a transfer film. This functionalisation may also be designed in the form of a vacuum coating, a paint or a sol-gel layer. After the transfer of the microhole structure this may be coated. This variant has the advantage that the microhole structure is largely resistant with respect to chemical or physical attacks. The second variant is the lamination of the obliquely coated substrate on the glass disk. For this application, materials with a large conductivity (e.g. metals) are particularly suitable.

1. A method for manufacturing microhole structures, with which a relief structure on the surface of a substrate is obliquely coated with the material of the microhole structure, wherein one uses a relief structure of a continuous network of the first surface regions whose local surface normal vectors enclose a small angle with the unit vector of the surface, and of second surface regions which are surrounded by the first surface regions and whose surface normal vectors enclose a small angle with the direction vector of the coating.

2. A method according to claim 1, characterized in that the relief structure of the substrate comprises cylinder-shaped, truncated cone shaped or parallelepiped projections on an at least approximate plane surface.

3. A method according to claim 1, characterized in that the relief structure of the substrate comprises cylinder-shaped, truncated cone shaped or parallelepiped recesses in at least approximate plane surface.

4. A method according to claim 1, characterized in that the relief structure of the substrate is formed by replication of an original structure.

5. A method according to claim 1, characterized in that the relief structure of the substrate or the original structure is formed by a photo-lithographic method.

6. A method according to claim 5, characterized in that the relief structure of the substrate or the original structure is formed by interference lithography.

7. A method according to claim 6, characterized in that the relief structure of the substrate, or the original structure is formed by an interference lithographic method with a multiple exposure at different angles.

8. A method according to claim 1, characterised in that for manufacturing a microhole structure for the radiation filtration one uses a substrate which is transparent to electromagnetic radiation of a certain frequency range.

9. A method to claim 1, characterized in that for manufacturing a microscreen for the fine filtration, the obliquely coated substrate on the coating side is provided with a wide-meshed support grid and subsequently the substrate material is removed.

10. A method according to claim 9, characterized in that the wide-meshed support grid is manufactured by way of selective galvanic reinforcement.

11. A method according claim 1, characterized in that for the manufacture of a microhole structure for the shielding of electromagnetic radiation, the material of he microhole structure which is deposited by way of oblique coating is transferred from the substrate onto a glass surface.

12. A method according claim 1, characterized in that for the manufacture of a microhole structure for the shielding of electromagnetic radiation, the substrate obliquely coated with the material of the microhole structure is lmainated onto a glass surface.

13. A method according to claim 1, characterized in that that the material of the microhole structure is a metal.

14. A method according to claim 13, characterized in that the material of the microhole structure which is deposited by way of oblique coating is galvanically reinforced.
